(19) United States
(12) Patent Application Publication
(10) Pub. No.: US 2025/0013144 A1
(43) Pub. Date: Jan. 9, 2025

(54) CARBON-BASED THIN FILM SHADOW MASK AND MANUFACTURING METHOD THEREFOR

(71) Applicant: GrapheneLab.Co.,Ltd, Hwaseong-si (KR)

(72) Inventors: Seung Il MOON, Ansan-si (KR); Young Duck KWON, Gwangmyeong-si (KR); Byong Wook YOO, Namyangju-si (KR); Jong Taik MOON, Seongnam-si (KR); Ki Soo KIM, Seongnam-si (KR); Sang Min LEE, Yongin-si (KR)

(21) Appl. No.: 18/898,438

(22) Filed: Sep. 26, 2024

Related U.S. Application Data
(63) Continuation of application No. PCT/KR2023/003995, filed on Mar. 27, 2023.

(30) Foreign Application Priority Data
Mar. 29, 2022 (KR) 10-2022-0038941

(51) Int. Cl. G03F 1/80; G03F 1/60; G03F 7/00; H10K 59/12

(52) U.S. Cl. CPC G03F 1/80; G03F 1/60; G03F 7/0005; H10K 59/1201

(57) ABSTRACT

A method for manufacturing a carbon-based thin film shadow mask includes the steps of a) forming a buffer layer on a substrate, b) depositing a metal layer on the buffer layer and then patterning the metal layer, c) forming an amorphous carbon layer on the patterned metal layer, d) forming a crystalline carbon layer on the buffer layer by switching the metal layer and the amorphous carbon layer, e) removing the amorphous carbon layer exposed to the outside, f) removing the metal layer, and g) separating the buffer layer and the crystalline carbon layer.

### CROSS-REFERENCE TO RELATED APPLICATIONS

The present application is a Continuation of International Application No. PCT/KR2023/003995 filed Mar. 27,2023, which claims priority from Korean Application No. 10-2022-0038941 filed Mar. 29, 2022. The aforementioned applications are incorporated herein by reference in their entireties.

### TECHNICAL FIELD

The present disclosure relates generally to a carbon-based thin film shadow mask and a manufacturing method therefor. More particularly, the present disclosure relates to a carbon-based thin film shadow mask manufactured by interlayer switching between a metal layer and a carbon-based thin film layer, and to a manufacturing method therefor.

### RELATED ART

Due to demand for display devices with high resolution and low power consumption, various display devices such as liquid crystal displays and electroluminescent displays are under development.

Electroluminescent displays are attracting attention as next-generation display devices because of their superior characteristics, such as low luminescence, low power consumption, and high resolution, compared to liquid crystal displays.

There are two types of electroluminescent displays: organic light-emitting diode displays and inorganic light-emitting diode displays. That is, depending on materials of a light-emitting layer, they can be classified into organic light-emitting diode displays and inorganic light-emitting diode displays.

Of these, organic light-emitting diode displays are attracting much attention because they have a wide viewing angle, fast response speed, and require low power consumption.

An organic material constituting the light-emitting layer may form a pattern for forming pixels on a substrate by a fine metal mask (FMM) method.

At this time, a fine metal mask, i.e., a deposition mask, may have a through-hole corresponding to the pattern to be formed on the substrate. After aligning the fine metal mask on the substrate, the organic material may be deposited to form red, green, and blue patterns that form pixels.

Recently, ultra-high definition (UHD) displays have been demanded for various electronic devices such as virtual reality (VR) devices. Fulfilling this demand requires a fine metal mask with microscopic through-holes capable of forming ultra-high definition (UHD) patterns.

For the manufacture of the fine metal mask (FMM), etching and electroforming methods are used in general.

The etching method is difficult to use to create high-resolution pixels, so the electroforming method is mainly used.

However, the electroplating method is not suitable for mass production due to its low yield.

Additionally, there is also used a laser etching method. This method is difficult to produce a fine pattern with resolution higher than UHD, and in particular, there are limitations in lowering the coefficient of thermal expansion (CTE).

The document of related art includes Korean Patent Application Publication No. 10-2021-0094261.

### SUMMARY

Accordingly, the present disclosure has been made keeping in mind the above problems occurring in the related art, and an objective of the present disclosure is to provide a carbon-based thin film shadow mask that maintains high resolution and low CTE by graphene synthesis, and a manufacturing method therefor.

In order to accomplish the above objective, the present disclosure provides a method for manufacturing a carbon-based thin film shadow mask, the method including: a) forming a buffer layer on a substrate; b) depositing a metal layer on the buffer layer and then patterning the metal layer; c) forming an amorphous carbon layer on the patterned metal layer; d) forming a crystalline carbon layer on the buffer layer by switching the metal layer and the amorphous carbon layer; e) removing the amorphous carbon layer exposed to the outside; f) removing the metal layer; and g) separating the buffer layer and the crystalline carbon layer.

This may enable a thin film shadow mask with a small thickness to be easily manufactured.

Here, in step f), the metal layer may be removed by an etching process.

Additionally, the buffer layer may be a single thin film or a heterogeneous multi-layer thin film made of at least one selected from the group consisting of a nitride film (SiNₓ) and an oxide film (SiO₂).

This may increase adhesion between the finally formed graphene and the buffer layer, thereby preventing the graphene from being peeled off during a subsequent etching process of the metal layer.

Additionally, the metal layer may be made of at least one material selected from the group consisting of transition metals such as copper, nickel, and platinum that easily absorb carbon.

This may prevent the metal layer from diffusing on the substrate.

Additionally, a thickness (ta-C) of the amorphous carbon layer and a thickness (tm) of the metal layer may be deposited to satisfy the following formula.

$$ta - C / tm \geq 0.9 \qquad [ Formula ]$$

This may enable uniform graphene to be formed during heat treatment.

Additionally, step d) may be performed by heat treatment at 500° C. to 700° C. in an argon, nitrogen, and inert gas atmosphere.

Additionally, step f) may be performed by a wet-etching method.

Additionally, the wet-etching method may be performed using sulfuric acid, hydrogen peroxide, and a heterocycle system.

Additionally, the wet-etching method may be performed using nitric acid and a heterocycle system.

This may minimize the effect on the entire structure including the graphene layer during the etching process.

Additionally, step d) may include: weakening a covalent bond of the amorphous carbon layer in contact with the metal layer; diffusing carbon in the amorphous carbon layer into the metal layer; growing graphene seeds at an interface between the amorphous carbon layer and the metal layer; growing graphene toward a lower part of the metal layer and diffusing the metal layer toward the amorphous carbon layer, causing crystals to grow in a direction that lowers interfacial energy; and completing the growing of the graphene and planarizing a surface of the metal layer that is grown on the graphene and crystallized.

According to a carbon-based thin film shadow mask and a manufacturing method therefor according to the present disclosure, a carbon-based thin film shadow mask can be manufactured and provided over a large area with a small thickness.

By providing a shadow mask with a small thickness, a shadow effect can be minimized, enabling formation of fine patterns and production of high-resolution patterns.

Additionally, by providing a shadow mask made of carbon, the coefficient of thermal expansion can be lowered.

### BRIEF DESCRIPTION OF THE DRAWINGS

FIG. 1 is a flowchart illustrating a method for manufacturing a carbon-based thin film shadow mask according to an embodiment of the present disclosure.

FIGS. 2A to 2G are schematic sectional configuration views illustrating the method for manufacturing the carbon-based thin film shadow mask according to the embodiment of the present disclosure.

FIGS. 3A to 3F are schematic views illustrating a graphene production process.

FIG. 4 is a view illustrating a shadow effect.

### DETAILED DESCRIPTION

The above and other objectives, features, and advantages of the present disclosure will be clearly understood from the more particular description of exemplary embodiments of the present disclosure. The present disclosure may, however, be embodied in different forms and should not be construed as limited to the embodiments set forth herein. Rather, these embodiments are provided so that this disclosure is thorough and complete and fully conveys the present disclosure to those skilled in the art.

In this specification, when an element is referred to as being on another element, it can be formed directly on the other element or intervening elements may be present therebetween. Further, in the drawings, the thicknesses of elements may be exaggerated for effective explanation of technical contents.

In this specification, although the terms first, second, etc. may be used to describe various elements, these elements should not be limited by these terms. These terms are only used to distinguish one element from another. The embodiments described and illustrated herein include their complementary embodiments.

Hereinbelow, a carbon-based thin film shadow mask and a manufacturing method therefor according to an embodiment of the present disclosure will be described in detail with reference to the accompanying drawings.

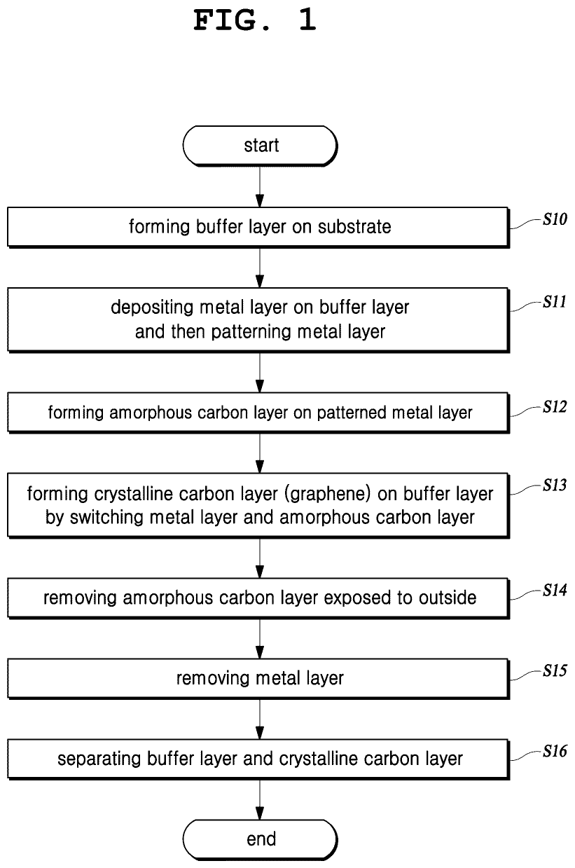

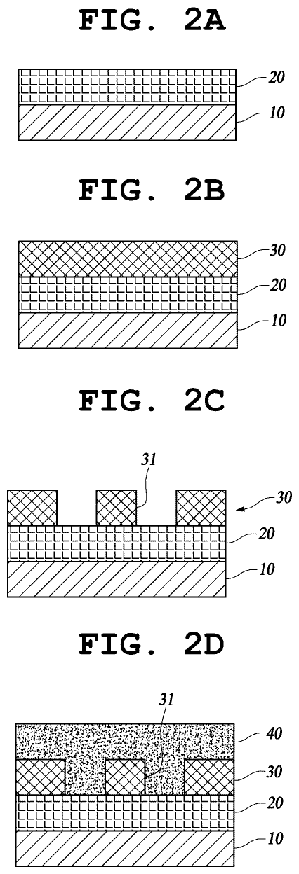

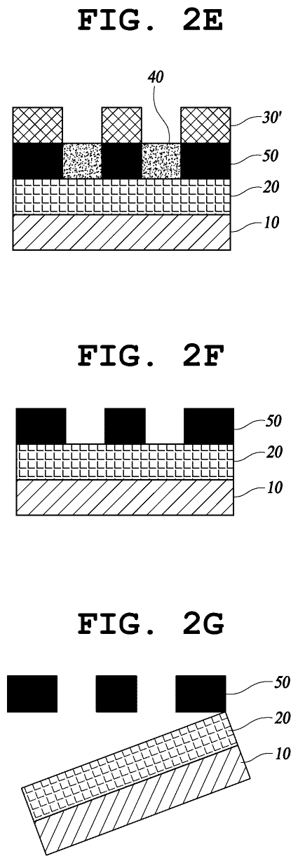

Referring to FIGS. 1 to 2G, a method for manufacturing a carbon-based thin film shadow mask according to an embodiment of the present disclosure includes the steps of: a) forming a buffer layer 20 on a substrate 10 (S10); b) depositing a metal layer 30 on the buffer layer 20 and then patterning the metal layer (S11); c) forming an amorphous carbon layer 40 on the patterned metal layer 30 (S12); d) forming a crystalline carbon layer 50 on the buffer layer 20 by switching the metal layer 30 and the amorphous carbon layer 40 (S13); e) removing the amorphous carbon layer 40 exposed to the outside (S14); f) removing the metal layer 30′ exposed to the outside (S15); and g) separating the buffer layer 20 and the crystalline carbon layer 50 (S16).

Here, the substrate 10 includes a buffer layer 20 that suppresses the metal layer 30 from diffusing on a silicon substrate, and it is preferable that the buffer layer 20 includes at least one material selected from the group consisting of SiNₓ, SiO₂, and Mo₂C and amorphous carbon. That is, the buffer layer 20 serves to prevent a material resistant to KOH or a material of the metal layer 30 (metal catalyst) from diffusing on the substrate 10.

The buffer layer 20 is a compound that does not react with a metal deposited on the substrate 10 and is made of at least one selected from the group consisting of SiNₓ, SiO₂, and heterogeneous multi-layer material. The buffer layer 20 has increased adhesion to finally formed graphene, thereby preventing it from being peeled off during a subsequent etching process of the metal layer 30.

It is preferable that the metal layer 30 is made of at least one material selected from the group consisting of nickel, cobalt, iron, iridium, chromium, manganese, platinum, and ruthenium.

Additionally, it is preferable that a thickness ta-C of the amorphous carbon layer 40 and a thickness tm of the metal layer 30 are deposited to satisfy the following formula.

$$ta - C / tm \geq 0.9 \qquad [ Formula ]$$

As described above, when the thicknesses of the amorphous carbon layer 40 and the metal layer 30 are formed to satisfy the above formula, uniform graphene may be grown during heat treatment.

According to the present disclosure having the above configuration, first, as illustrated in FIG. 2A, the buffer layer 20 is deposited on the substrate 10 having an etching stopper (S10), and then, as illustrated in FIG. 2B, the metal layer 30 is deposited on the buffer layer 20 to a predetermined thickness (S11). Then, as illustrated in FIG. 2C, the metal layer 30 is patterned to form a pattern portion 31. The buffer layer 20 is exposed to the outside through the pattern portion 31.

Then, as illustrated in FIG. 2D, the amorphous carbon layer 40 is deposited on the patterned metal layer 30 and the pattern portion 31 to a predetermined thickness so as to satisfy the above formula, as described above (S12).

The substrate 10 subjected to step S12 is placed in a furnace and heated to switch the metal layer 30 and the amorphous carbon layer 40 (S13). Then, as illustrated in FIG. 2E, the metal layer 30 remaining patterned and the amorphous carbon layer 40 located thereunder are switched to form the crystalline carbon layer 50 (graphene) on the buffer layer 20.

At this time, it is preferable that heat treatment in step S13 is performed at 500° C. to 700° C. in an argon, nitrogen, and inert gas atmosphere. Here, the temperature and time for heat treatment may be selectively determined depending on the type of metal layer 30 and the thickness of each deposited layer.

Then, as illustrated in FIG. 2E, the amorphous carbon layer 40 remaining in the pattern portion 31 without being switched and being exposed to the outside is removed (S14). The amorphous carbon layer 40 remaining exposed to the outside may be removed by an etching process.

Then, as illustrated in FIG. 2F, the metal layer 30′ switched and exposed to the outside is removed (S15). As a method for removing the metal layer 30 in step S15, a wet etching method may be used. Here, etching of the metal layer 30 may be generally achieved by a wet etching method that involves dipping in an etchant such as NHO₃, CH₃COOH, FeCl₃, or CAN. However, since the metal layer 30 is too thin, a general etchant may affect the entire structure including the graphene layer 50. Additionally, when the metal layer 30 is a nickel catalyst, residue may remain.

Therefore, it is preferable to use a very mild etchant that leaves no residue. To this end, it is preferable to perform the etching process for 30 minutes to 1 hour using sulfuric acid, hydrogen peroxide, and a heterocycle system or nitric acid and a heterocycle system.

When the metal layer 30 is removed in this manner, the graphene layer 50 remains in a patterned form on the buffer layer 20. The remaining graphene layer 50 is separated from the buffer layer 20 by a separation (release) process (S16), thereby completing a thin film shadow mask.

Meanwhile, as described above, in order to manufacture a thin film shadow mask, graphene may be grown directly over a large area by interlayer switching between the amorphous carbon layer and the metal layer. A specific method for this, i.e., step d), is described as follows.

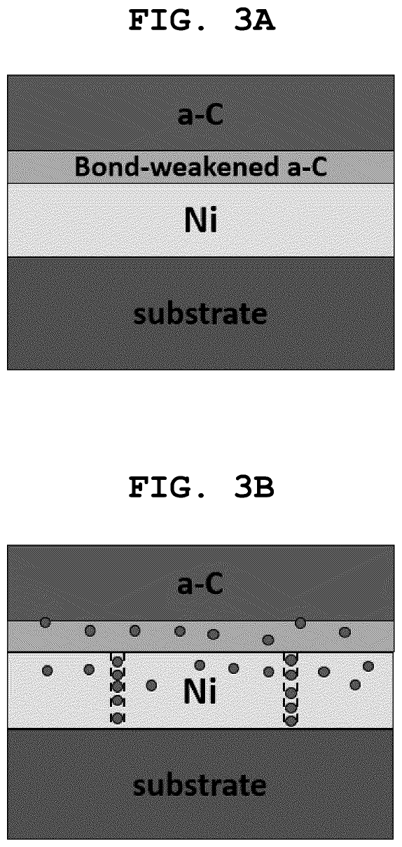

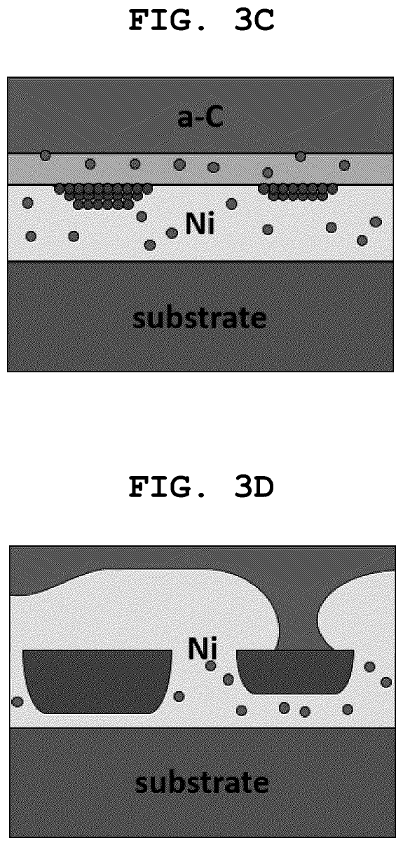

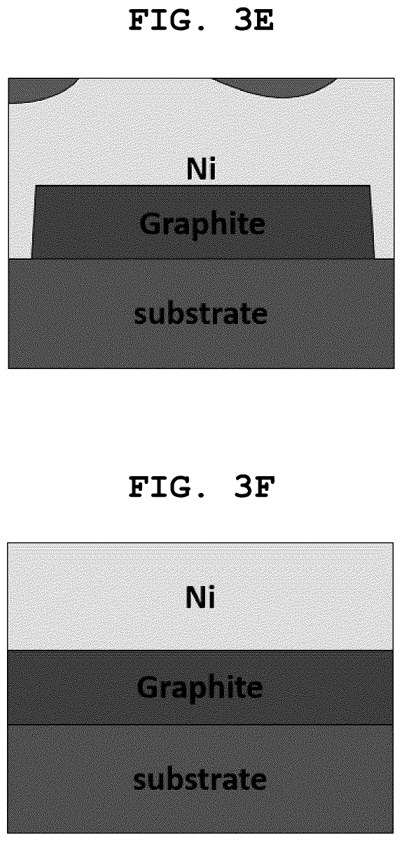

First, as illustrated in FIG. 3A, a covalent bond of the amorphous carbon layer in contact with the metal layer (metal catalyst) is weakened.

Then, as illustrated in FIG. 3B, carbon in the amorphous carbon layer diffuses into the metal layer.

Then, as illustrated in FIG. 3C, graphene seeds grow at the interface between the amorphous carbon layer and the metal layer.

Then, as illustrated in FIG. 3D, graphene grows toward a lower part of the metal layer, and the metal layer diffuses toward the amorphous carbon layer, causing crystals to grow in a direction that lowers interfacial energy.

Finally, as illustrated in FIGS. 3E and 3F, the growing of graphene is completed, and a surface of the metal layer that is grown on graphene and crystallized is planarized, thereby directly growing graphene over a large area.

As described above, the thin film shadow mask (FMM) manufactured by the method according to the embodiment of the present disclosure is characterized by being manufactured by a direct growth method of graphene, so it has advantages of forming a fine pattern, producing a high-resolution pattern, minimizing a shadow effect because of its small thickness, and lowering the coefficient of thermal expansion.

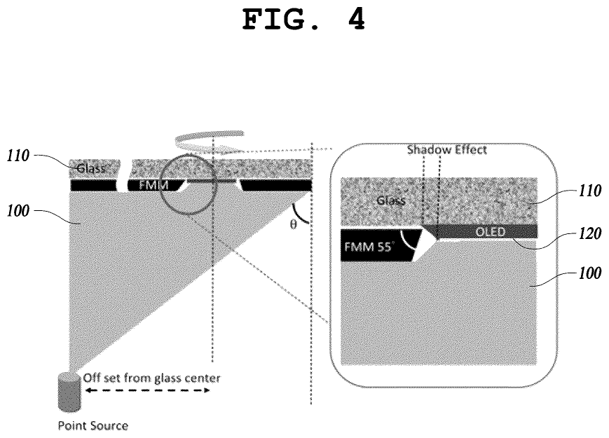

That is, as illustrated in FIG. 4, a shadow effect that is accompanied when pixels are deposited on a substrate or glass occurs depending on the thickness of the mask. Therefore, when the mask is thick, the area where the shadow effect occurs increases, which limits formation of fine patterns.

Meanwhile, according to the embodiment of the present disclosure, since the thin film shadow mask is manufactured thinly, i.e., with a thickness of several microns to nanometers, it hardly causes the shadow effect and thus is suitable for forming a fine pattern. Therefore, it is possible to manufacture high-resolution OLEDS.

Additionally, since graphene itself grown by a switching method has the characteristic of shrinking when the temperature rises, it is possible to lower the coefficient of thermal expansion due to the characteristic of graphene.

Those skilled in the art will appreciate that various alternatives, modifications, and equivalents are possible, without changing the spirit or essential features of the present disclosure. Therefore, preferred embodiments of the present disclosure have been described for illustrative purposes, and should not be construed as being restrictive. The scope of the present disclosure is defined by the accompanying claims rather than the description which is presented above. Moreover, the present disclosure is intended to cover not only the exemplary embodiments, but also various alternatives, modifications, equivalents and other embodiments that may be included within the spirit and scope of the present disclosure as defined by the appended claims.

### Description of the Reference Numerals in the Drawings

10 substrate
20 buffer layer
30,30′ metal layer
31 pattern portion
40 amorphous carbon layer
50 crystalline carbon layer

What is claimed is:

1. A method for manufacturing a carbon-based thin film shadow mask, the method comprising:
a) forming a buffer layer on a substrate;
b) depositing a metal layer on the buffer layer and then patterning the metal layer;
c) forming an amorphous carbon layer on the patterned metal layer;
d) forming a crystalline carbon layer on the buffer layer by switching the metal layer and the amorphous carbon layer;
e) removing the amorphous carbon layer exposed to outside;
f) removing the metal layer; and
g) separating the buffer layer and the crystalline carbon layer.

2. The method of claim 1, wherein in step f), the metal layer is removed by an etching process.

3. The method of claim 1, wherein the buffer layer is a single thin film or a heterogeneous multi-layer thin film made of at least one selected from the group consisting of a nitride film (SiNₓ) and an oxide film (SiO₂).

4. The method of claim 1, wherein the metal layer is made of at least one material selected from the group consisting of nickel, cobalt, iron, iridium, chromium, manganese, platinum, and ruthenium.

5. The method of claim 1, wherein the substrate includes a buffer layer that suppresses the metal layer from diffusing on a silicon substrate, and
wherein the buffer layer comprises:
at least one material selected from the group consisting of SiNₓ, SiO₂, and MO₂C; and
amorphous carbon.

6. The method of claim 1, wherein a thickness (ta-C) of the amorphous carbon layer and a thickness (tm) of the metal layer are deposited to satisfy the following formula,
$$ta - C / tm \geq 0.9 . \qquad [ Formula ]$$

7. The method of claim 1, wherein step d) is performed by heat treatment at 500° C. to 700° C. in an argon, nitrogen, and inert gas atmosphere.

8. The method of claim 1, wherein step f) is performed by a wet-etching method.

9. The method of claim 8, wherein the wet-etching method is performed using sulfuric acid, hydrogen peroxide, and a heterocycle system.

10. The method of claim 8, wherein the wet-etching method is performed using nitric acid and a heterocycle system.

11. The method of claim 1, wherein step d) comprises:
weakening a covalent bond of the amorphous carbon layer in contact with the metal layer;
diffusing carbon in the amorphous carbon layer into the metal layer;
growing graphene seeds at an interface between the amorphous carbon layer and the metal layer;
growing graphene toward a lower part of the metal layer and diffusing the metal layer toward the amorphous carbon layer, causing crystals to grow in a direction that lowers interfacial energy; and
completing the growing of the graphene and planarizing a surface of the metal layer that is grown on the graphene and crystallized.

12. A carbon-based thin film shadow mask manufactured by the method of claim 1.
